(19) United States
(12) Patent Application Publication
(10) Pub. No.: US 2009/0034081 A1
(43) Pub. Date: Feb. 5, 2009

(54) Vacuum Evaporation Method for Forming a Multilayer Film Filter on a Plastic Component and Multi-Layer Film Filter Optical Image-Capturing Assembly with the Plastic Component

(76) Inventors: Kuo-Chiang Chu, Taichung (TW); Chien-Pang Chang, Taichung (TW)

Correspondence Address: Dr. BANGER SHIA, 102 Lindencrest Ct., Sugar Land, TX, 77479-5201, US

(21) Appl. No.: 11/845,078

(22) Filed: Aug. 26, 2007

(30) Foreign Application Priority Data
Aug. 3, 2007 (TW) 096128745

(51) Int. Cl. G02B 1/10; B05D 5/06; C23C 14/00

(52) U.S. Cl. 359/588; 427/162; 427/523

(57) ABSTRACT

A vacuum evaporation method for forming a multi-layer film filter on a plastic optical component and a multi-layer film filter optical image-capturing assembly with the plastic optical component, in which the multi-layer film filter generally refers to various filters produced by adopting the optical interference principle. During the evaporation operation, the evaporation time of each film is not more than four minutes, the distance between the evaporation source and the plastic optical assembly must be more than 100 centimeters, and the ion assisted deposition is performed when the high refraction film and low refraction film are alternately laminated one upon the other to form more than 40 layers of films. The optical image capture assembly with the plastic optical component can be used without additionally adopting a multilayer film filter, thus effectively reducing the volume and the cost.

### BACKGROUND OF THE INVENTION

1. Field of the Invention

The present invention relates to a vacuum evaporation method for forming a multi-layer film filter on a plastic optical component and a multi-layer film filter optical image-capturing assembly with the plastic component, and more particularly to replacing the filters of various miniaturized plastic optical image-capturing assemblies.

2. Description of the Prior Art

With the miniaturization and precisation of the consumer electronic products, such as the digital camera, mobile phone, personal digital assistant (PDA), CD-ROM, multi-function video camera, or even the TV game etc, the optical image-capturing assembly will be required with higher performance. Therefore, the future designed and developed optical image capturing assembly must meet the requirements of both the miniaturization and the high resolution.

Referring to FIG. 1 which shows the optical image-capturing assembly used in most of the mobile phones or the personal digital assistants (PDA), the optical image-capturing assembly comprises a plurality of optical components 11 and a multi-layer film filter 12 (including a glass substrate 121 and multiple layers of filter films 122), that are laminated in a lens barrel 10 in the same way (the filter in this example is an IR cut filter). The reason for using the filter 12 is that, the sensors (CCD, CMOS) used in this kind of products can sense the infrared ray which cannot be sensed by the human eyes. If the multi-layer film filter 12 is not used, the photo will present the visible light image and the infrared image, thus causing the image distortion. In order to reduce the infrared image distortion to a minimum, the optical image-capturing assembly must be installed with a multi-layer film filter 12 to block the infrared rays, so as to make the sensor receive the visible light only.

In the same way, in order to meet the wavelength requirement of the optical image component, other consumer electronic products with the optical component are also equipped with other types of multi-layer filters. For example, the IR motion sensor must include an IR penetrating filter to block the visible light and let the infrared rays penetrate only, the CD-ROM reader head must include a polarizer and a spectroscope to make the specific polarized laser light shuttle in the optical path, and the multi-function projector must include the primary color filter of red, green and blue to split the white visible light into the three primary colors of red, green and blue for processing the image.

The principle of the abovementioned multi-layer film is that, by making use of the films with different refractive indexes, with the specific layer quantity and thickness, the light with specific wavelength can be filtered by the way of optical wave interference. Based on the symmetrical film theory put forward by L. I Epstein in 1952, the film H with high refractive index and the film L with lower-refractive index satisfy the relation:

$${( \frac{H}{2} L \frac{H}{2} )}^{s} or {( \frac{L}{2} H \frac{L}{2} )}^{s}$$

(s represents the cycle) first, and then adjusting the film thickness according to the required specification can form the specific layers and thickness.

As to the fabrication of the multi-layer filter, it is to pile up multiple layers of filter films 122 on a large glass substrate by the physical vacuum evaporation way and continue with the manufacture process like cutting, edge-trimming and cleaning, then the multi-layer film filter can be finished. It is to be noted that, in order to achieve the objective of filtering the light within a certain wavelength range, the number of layers of the multi-layer optical filter films is usually more than 40.

As known from the abovementioned conventional technology, the multi-layer film filter can meet the requirements of the different performances of the optical component. However, based on the Snell's law, the glass substrate of the multi-layer film filter will cause the increase of the total optical path length. Since the optical path length is in inverse proportion to the refractive index in medium, namely, the optical path length is shortened in the glass substrate. Since the total optical path length of the imaging system is invariable, the optical path length shortened in the glass substrate must be added in the optical component to keep the total optical path length invariable. Such a result indicates that the volume of optical component will be increased due to the use of the multi-layer film filter. It goes against the optical image-capturing assembly which requires to be lighter, thinner, shorter and smaller continuously.

In addition, considering the cost, the use of the multi-layer film filter consequentially increases the material cost of the optical image-capturing assembly. One solution is to directly deposit the multi-layer optical filter film on the glass optical component by the evaporation method. Considering the high cost of the glass optical component, the multi-layer optical filter film is expected to be directly deposited on the plastic optical component by the evaporation method. However, because the operation temperature of the evaporation source easily exceeds 2500° C., and the layer quantity of the multi-layer optical filter film is often more than 40, the temperature of the substrate exposed in the high temperature environment for a long time is to be between 250° C. and 350° C. Such a high temperature is helpful to form the tight film structure, but it cannot be applied to the plastic substrate whose softening temperature is from 80° C. to 150° C.

The present invention has arisen to mitigate and/or obviate the afore-described disadvantages.

### SUMMARY OF THE INVENTION

Considering the abovementioned conventional optical image-capturing assembly, and under the limitation of the cost of the optical image-capturing assembly, the applicant of the present invention has developed a vacuum evaporation method for forming a multi-layer film filter on a plastic optical component and a multi-layer film filter optical image-capturing assembly with the plastic optical component.

The multi-layer filter film is directly evaporated on one of the plastic optical components of the optical image-capturing assembly to replace the multi-layer film filter which uses the glass as the substrate. The optical image-capturing assembly of the present invention is unnecessary to be equipped with multi-layer film filter additionally, thus not only saving the raw material and the assembly cost of the optical image-capturing assembly, but also effectively reducing the volume of the optical image-capturing assembly.

The primary objective of the present invention is to provide a vacuum evaporation method for forming a multi-layer film filter on a plastic optical component and a multi-layer film filter optical image-capturing assembly with the plastic optical component. On the plastic optical component is directly deposited multi-layer filter film by vacuum evaporation method to replace the multi-layer film filter, so that the volume of the optical image-capturing assembly is reduced.

In order to achieve the abovementioned objective, on the plastic optical component is directly formed multiple layers of filter films including the films with high refractive index and the films with low refractive index by the vacuum evaporation method. According to the requirements, the multi-layer filter film can be applied onto any predetermined plastic optical component, so as to effectively reducing the volume of the optical image-capturing assembly.

The second objective of the present invention is to provide a vacuum evaporation method for forming a multi-layer film filter on a plastic optical component and a multi-layer film filter optical image-capturing assembly with the plastic component. Under the premise that the plastic optical component is not affected by the temperature, a fine multi-layer filter film can be formed by the vacuum evaporation method.

As known from the conventional optical image-capturing assembly, high temperature severely affects the plastic optical component. In order to prevent the plastic optical component from being affected by the high temperature, the present invention restricts the vacuum evaporation time of each film not more than 4 minutes to reduce the heating effect from evaporation source to the plastic optical component. Increasing the distance between the evaporation source and the plastic optical component can reduce the heat received by the plastic optical component. Thereby, the present invention restricts the distance between the evaporation source and the plastic optical component more than 100 centimeters to avoid excessive heat transmitted to the plastic optical component from the evaporation source.

However, even though the abovementioned protect measures are used to prevent the plastic optical component from being affected by the evaporation source, there is still part of the heat of the evaporation source to be transmitted to the plastic optical component. Thereby, the present invention restrict that, each layer of film should stand for one to four minutes after being evaporated, so as to make the plastic optical component release the heat received form the evaporation through heat radiation. It is to be noted that, as long as the absolute temperature of the object is greater than 0, the object has the heat radiation effect, namely, the vacuum evaporation apparatus is also a heat radiation source which cannot be neglected. The greater the heat radiation difference between the plastic optical component and the vacuum evaporation apparatus is, the better the radiation cooling effect is. Hence, during the evaporation operation, the cooling water whose temperature is lower than 25° C. is used to cool the vacuum evaporation apparatus, so as to reducing the radiation heat released by the vacuum evaporation apparatus, thus facilitating accelerating the radiation cooling effect of the plastic optical component.

Though the abovementioned measures, the temperature of the plastic optical component is controlled to be lower than 80° C. The low temperature evaporation process has bad influence on the tightness and the adhesion of the multi-layer filter film, so the ion assisted deposition must be applied to improve the tightness and the adhesion of the multi-layer filter film during the vacuum evaporation process.

### BRIEF DESCRIPTION OF THE DRAWINGS

FIG. 1 is an illustrative view of a conventional optical image-capturing assembly;

FIG. 2 is an illustrative view of an optical image-capturing assembly in accordance with the present invention;

FIG. 3 is an illustrative view of another optical image-capturing assembly in accordance with the present invention;

FIG. 4 shows the IR cut spectrum in accordance with the present invention; and

FIG. 5 shows the IR penetrating spectrum in accordance with the present invention.

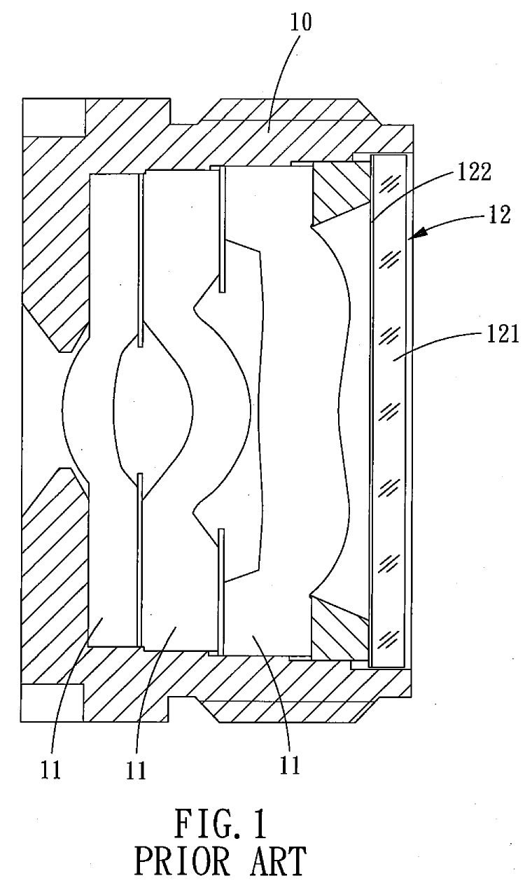

Appendix I shows the test result of the conventional optical image-capturing assembly and the optical image-capturing assembly in accordance with the present invention; and

Appendix II shows another test result of the conventional optical image-capturing assembly and the optical image-capturing assembly in accordance with the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

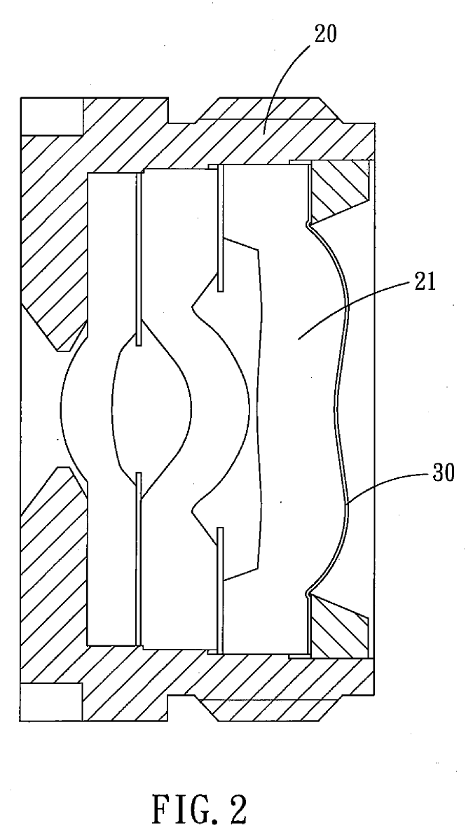

Referring to FIG. 2, this embodiment is a substitute for an IR cut filter The drawings illustrate a vacuum evaporation method for forming a multi-layer film filter on a plastic optical component and an optical image-capturing assembly with the plastic optical component made by the method in accordance with the present invention.

The vacuum evaporation method for forming a multi-layer film filter on a plastic optical component is to apply the multiple layers of filter films (IR cut film 30) onto a surface of a predetermined plastic optical component 21. The evaporation time of each layer of film is not more than four minutes. The distance between the evaporation source and the plastic optical component 21 is more than 100 centimeters. Each layer of film should stand for one to four minutes after being evaporated to control the temperature of the plastic optical component 21 lower than 80° C., and carry out the ion assisted deposition. The optical image-capturing assembly needn't to be equipped with the IR cut filter.

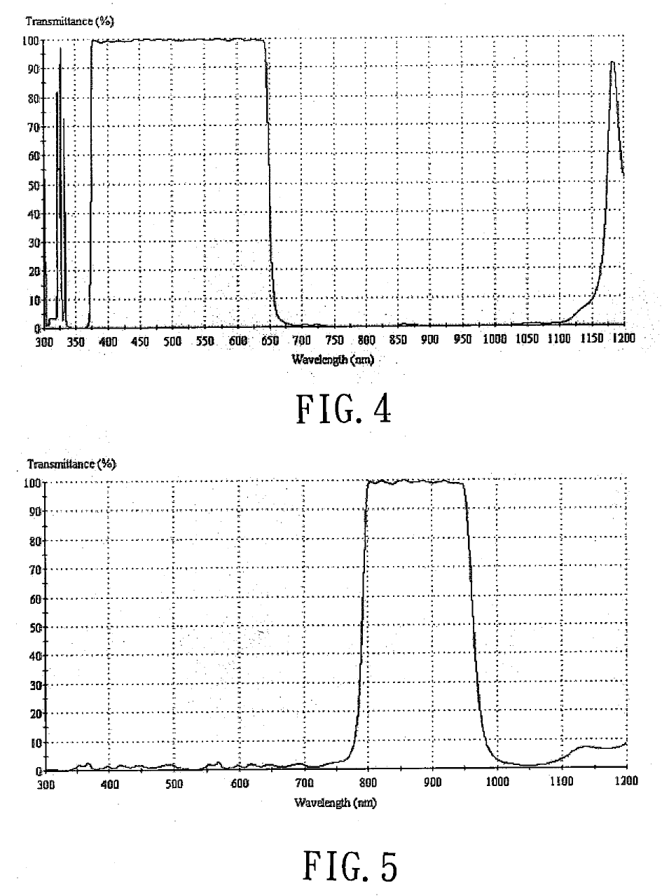

As shown in FIG. 2 which shows that three optical components 21, 22, 23 are piled up in the lens barrel 20, on the surface of the plastic optical component 21 is evaporated the IR cut filter film 30. The film 30 includes 26 layers of Nb₂O₅ films with high refractive index and 26 layers of SiO₂ films with low refractive index, that are alternately laminated one upon the other to form a 52-layer film (as shown in FIG. 4).

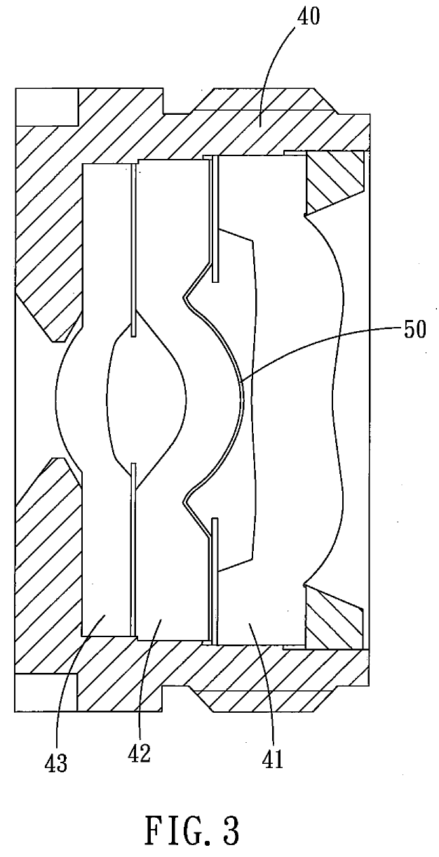

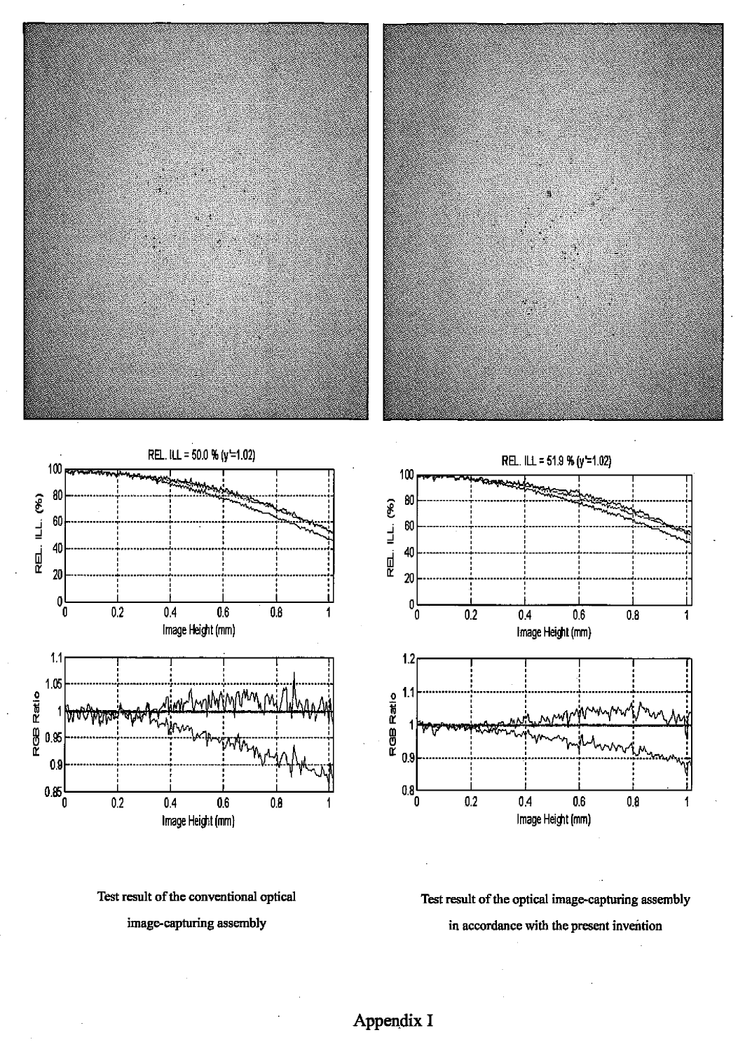

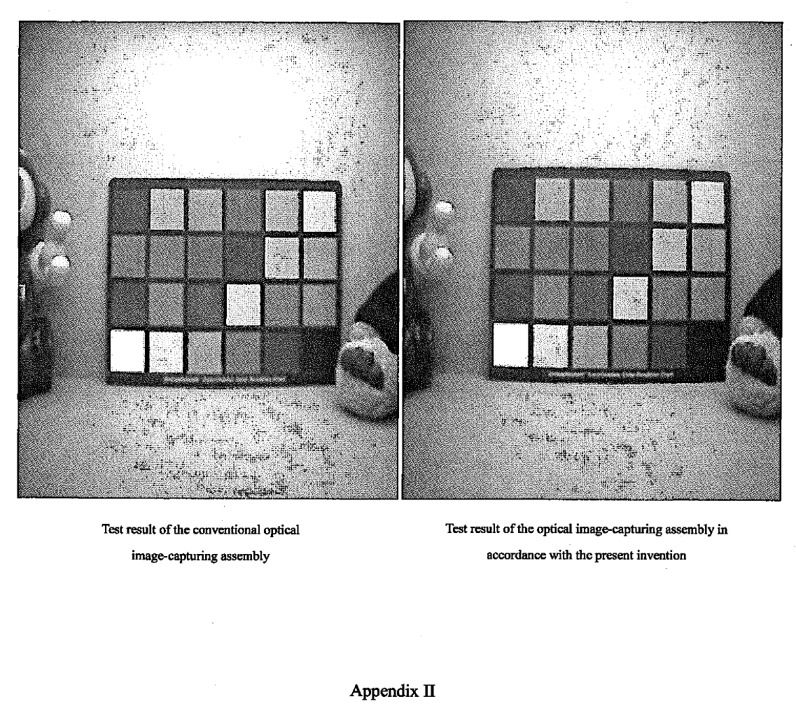

As shown in FIG. 3, which shows that the present invention is applied to the infrared motion sensor, the lens barrel 40 includes the plastic optical components 41, 42, 43 successively. On the surface of the plastic optical component 42 is evaporated the infrared penetrating film 50. The infrared penetrating film 50 includes Ti3O5 films with high refractive index and SiO2 films with low refractive index, that are alternately laminated one upon the other to form to form 46-layer film by the physical vacuum evaporation method (as shown in FIG. 5).

Finally, please refer to appendix I, II together, the present invention applied to substituting the IR cut filter is compared with the conventional optical image-capturing assembly. Focusing on the function comparison between them, the practical image-capturing test will be carried out by the conventional image capturing assembly (left image in appendix I) and the optical image-capturing assembly of the present invention (right image in appendix II) together with the same sensor module. Appendix I shows that the two optical image-capturing assemblies take a photo of an uniform black light respectively, based on the analysis of the photos, there are no difference between the two optical image-capturing assemblies, no matter in illumination distribution or intensity distribution of RGB (red, green, blue). In addition, in the test of taking a photo of a color panel (as shown in Appendix II), the two optical image-capturing assemblies are the same in color and luster and the resolution of the 24 colors in the color panel.

While we have shown and described various embodiments in accordance with the present invention, it is clear to those skilled in the art that further embodiments may be made without departing from the scope of the present invention.

What is claimed is:

1. A vacuum evaporation method for forming a multi-layer film filter on a plastic optical component comprising: depositing multiple layers of filter films on a plastic optical component by a vacuum evaporation method, the multiple layers of filter films including multiple layers of films with high refractive index and multiple layers of films with low refractive index that are alternately laminated one upon the other.

2. The vacuum evaporation method for forming a multi-layer film filter on a plastic optical component as claimed in claim 1, wherein a distance between an evaporation source and the plastic optical component is more than 100 centimeters during evaporating operation.

3. The vacuum evaporation method for forming a multi-layer film filter on a plastic optical component as claimed in claim 1, wherein each layer of film should stand for one to four minutes after being evaporated.

4. The vacuum evaporation method for forming a multi-layer film filter on a plastic optical component as claimed in claim 3, wherein the film with high refractive index or the film with low refractive index is formed by adopting a vacuum evaporation apparatus, and the vacuum evaporation apparatus uses a cooling water whose temperature is lower than 25° C.

5. The vacuum evaporation method for forming a multi-layer film filter on a plastic optical component as claimed in claim 3, wherein an evaporation time of each film with high refractive index or each film with low refractive index deducted the standing time is controlled not more than 4 minutes.

6. The vacuum evaporation method for forming a multi-layer film filter on a plastic optical component as claimed in claim 1, wherein the films with high refractive index and the films with low refractive index are alternately laminated one upon the other to obtain more than 40 layers of films.

7. The vacuum evaporation method for forming a multi-layer film filter on a plastic optical component as claimed in claim 1, wherein a temperature of the plastic optical component is not more than 80° C. during a vacuum evaporation of the film with high refractive index and the film with low refractive index.

8. The vacuum evaporation method for forming a multi-layer film filter on a plastic optical component as claimed in claim 1, wherein an ion assisted deposition is applied to the plastic optical component during the evaporation operation.

9. The vacuum evaporation method for forming a multi-layer film filter on a plastic optical component as claimed in claim 1, wherein the film with high refractive index is made of Ti₃O₅ material, and the film with low refractive index is made of SiO₂ material.

10. The vacuum evaporation method for forming a multi-layer film filter on a plastic optical component as claimed in claim 1, wherein the film with high refractive index is made of Nb₂O₅ material, and the film with low refractive index is made of SiO₂ material.

11. A multi-layer film filter optical image-capturing assembly with a plastic optical component comprising:
at least plastic optical component located in the optical image image-capturing assembly; and
a multi-layer filter film including films with high refractive index and films with low refractive index, that are alternately laminated one upon the other on the plastic optical component.

12. The multi-layer film filter optical image-capturing assembly with a plastic optical component as claimed in claim 11, wherein the films with high refractive index and films with low refractive index are alternately laminated one upon the other to form 40 layers of films to 60 layers of films.

13. The multi-layer film filter optical image-capturing assembly with a plastic optical component as claimed in claim 11, wherein a refractive index of the film with high refractive index is larger than 2.0, and a refractive index of the film with low high refractive index is smaller then 1.5.

14. The multi-layer film filter optical image-capturing assembly with a plastic optical component as claimed in claim 11, wherein the plastic optical component includes a flat surface or a curve surface.

15. The multi-layer film filter optical image-capturing assembly with a plastic optical component as claimed in claim 11, wherein the plastic optical component is located outside the optical image-capturing assembly.

16. The multi-layer film filter optical image-capturing assembly with a plastic optical component as claimed in claim 11, wherein the plastic optical component is located in the middle of the optical image-capturing assembly.
